(19) United States
(12) Patent Application Publication
(10) Pub. No.: US 2026/0260838 A1
(43) Pub. Date: Sep. 3, 2026

(54) APPLIED ELECTRON BEAM DEVICE AND ELECTRON BEAM GENERATION METHOD

(71) Applicant: Hitachi High-Tech Corporation, Minato-ku, Tokyo (JP)

(72) Inventors: Takashi OHSHIMA, Tokyo (JP); Tatsuro IDE, Tokyo (JP); Hideo MORISHITA, Tokyo (JP); Daichi TAKANE, Tokyo (JP); Yoichi OSE, Tokyo (JP); Junichi KATANE, Tokyo (JP)

(21) Appl. No.: 18/868,339

(22) PCT Filed: Jun. 3, 2022
(86) PCT No.: PCT/JP2022/022635

§ 371 Date: Nov. 22, 2024

(51) Int. Cl. H01J 37/073; H01J 37/22; H01J 37/244

(52) U.S. Cl. CPC H01J 37/073; H01J 37/22; H01J 37/244; H01J 2237/06333; H01J 2237/2482; H01J 2237/28

(57) ABSTRACT

In order to increase luminance of an electron beam emitted from a photocathode including a photoelectric film, second pulsed light that has a longer wavelength than first pulsed light is radiated to the photocathode in addition to the first pulsed light. According to an aspect of an applied electron beam device, the applied electron beam device includes a photocathode 1, a first pulsed light source 7 configured to emit first pulsed light, a second pulsed light source 8 configured to emit second pulsed light having a ring-shaped light intensity distribution, an excitation light optical system 21 configured to emit the first pulsed light and the second pulsed light in a manner of combining an optical path of the first pulsed light and an optical path of the second pulsed light, a condensing lens 2 configured to condense, on the photocathode, the first pulsed light and the second pulsed light emitted from the excitation light optical system, and an electron optical system configured to irradiate a sample 20 with the electron beam emitted from the photocathode.

### TECHNICAL FIELD

The present invention relates to an applied electron beam device and an electron beam generation method.

### BACKGROUND ART

In a high-resolution electron microscope, an electron source that has high luminance and emits an electron beam with a narrow energy width is essential. Further, in recent years, there has been progress in technology for pulsing an electron beam that serves as a probe in order to capture rapid time changes in addition to achieving high spatial resolution. A photocathode that generates pulsed electrons in response to the incidence of a light pulse is fairly useful for capturing a phenomenon that changes at high speed. A photoexcitation electron source using negative electron affinity (NEA) has a feature of high luminance, in which a work function of a semiconductor surface containing GaAs or the like is reduced by adding Cs, O, or the like, and electrons excited into a conduction band due to band-to band transition in response to light incidence are emitted into vacuum. This is because the photoexcitation electron source is a planar electron source, and although a focal point size of excitation light, which is a light source size, is large at about 1 μm, emitted electrons have good linearity.

PTL 1 discloses an electron gun using such a photocathode. PTL 1 discloses a structure of the electron gun in which a transparent substrate is used as the photocathode, specifically, a photoelectric film is attached to the transparent substrate, a condensing lens with a large numerical aperture (NA) of about 0.5 is placed close to the transparent substrate to focus excitation light onto the photoelectric film up to a diffraction limit, thereby creating a small electron light source, and an electron beam emitted from the electron light source into vacuum is used.

PTL 2 discloses that excitation light incident on a photocathode is two laser beams, one of the two laser beams is radially polarized light, and an electric field vector generated at a condensing position is perpendicular to a surface of the photocathode, thereby lowering an effective work function of the photocathode.

### CITATION LIST

### Patent Literature

PTL 1: JP2001-143648A
PTL 2: JP2008-288099A

### SUMMARY OF INVENTION

### Technical Problem

In order to further increase resolution of an electron microscope that uses a photoexcitation electron source as an electron source, it is desirable to further increase luminance of the photoexcitation electron source, but even when an intensity of excitation light is increased, a probe current obtained with continuous light does not increase beyond a certain point. This is because an amount of heat generation and an amount of charges accumulated on a surface increases as an emitted current amount increases, which limits an emitted current. One solution is to pulse the excitation light. Accordingly, accumulation of heat or charges on the surface can be reduced. In the case of a photocathode mainly including GaAs, laser light having a wavelength of 760 nm to 800 nm is suitable as an excitation light source. Examples of such a light source include a semiconductor diode and solid-state laser using a light-emitting crystal. Such a light source is useful for various measurements because pulsed light can be extracted and a pulse width and an interval can be controlled by an electric signal or an optical signal.

However, even when the excitation light is pulsed, there is a limitation on the luminance. Luminance of an electron source increases as an area of an emission source decreases. However, in the case of a photoexcitation electron source, a size of a cathode region for emitting electrons is a size of a spot formed by focusing excitation light on a photocathode, this size is determined by a wavelength of the excitation light, and it is difficult to reduce the size.

In the case of using a wide gap semiconductor, such as GaN or InGaN, that enables electrical conduction with a higher current density as a photoelectric film of a photocathode, since ionization energy of an acceptor doped inside is large and a hole density is low at room temperature, electrical resistance is high and an emitted current density is limited.

As disclosed in PTL 2, even when a radially polarized beam is radiated to generate an electric field vector perpendicular to the surface of the photocathode, since the electric field generated by light oscillates over time, electron emission increases or decreases, which limits improvement of luminance.

### Solution to Problem

An applied electron beam device according to an embodiment of the invention includes a photocathode including a photoelectric film, a first pulsed light source configured to emit first pulsed light, a second pulsed light source configured to emit second pulsed light having a longer wavelength than the first pulsed light and having a ring-shaped light intensity distribution, an excitation light optical system configured to emit the first pulsed light and the second pulsed light in a manner of combining an optical path of the first pulsed light and an optical path of the second pulsed light, a condensing lens configured to condense, on the photocathode, the first pulsed light and the second pulsed light that are emitted from the excitation light optical system, and an electron optical system configured to irradiate a sample with an electron beam emitted from the photocathode.

### Advantageous Effects of Invention

It is possible to increase luminance of the electron beam emitted from the photocathode. Other problems and novel features will become apparent from description of the present specification and the accompanying drawings.

### BRIEF DESCRIPTION OF DRAWINGS

FIG. 1 is a schematic view showing an applied electron beam device.

FIG. 2A is a view showing a configuration of an excitation light optical system.

FIG. 2B is a timing chart showing pulsed light.

FIG. 3 illustrates an example of an optical modulator (a phase mask).

FIG. 4A is a diagram showing a light intensity and electron distribution caused by first pulsed light.

FIG. 4B is diagram showing a light intensity distribution caused by second pulsed light.

FIG. 4C is diagram showing an electron distribution caused by the first and the second pulsed light.

FIG. 5A is a diagram showing an effect of the second pulsed light in Embodiment 1.

FIG. 5B is a diagram showing an effect of the second pulsed light in Embodiment 1.

FIG. 6 is a view showing a configuration of an excitation light optical system.

FIG. 7A shows an example of a spiral phase plate.

FIG. 7B is a diagram showing a light intensity distribution of the second pulsed light formed by the spiral phase plate.

FIG. 8A is a diagram showing an effect of the second pulsed light in Embodiment 2.

FIG. 8B is a diagram showing an effect of the second pulsed light in Embodiment 2.

FIG. 8C is a diagram showing an effect of the second pulsed light in Embodiment 2.

FIG. 9 is a timing chart showing pulsed light.

FIG. 10 is a diagram showing a configuration of an excitation light optical system.

FIG. 11A is a diagram showing an effect of the second pulsed light in Embodiment 2.

FIG. 11B is a diagram showing an effect of the second pulsed light in Embodiment 2.

FIG. 11C is a diagram showing an effect of the second pulsed light in Embodiment 2.

FIG. 12A is a view showing a radially polarized beam.

FIG. 12B is a view showing a radially polarized beam.

FIG. 13 is a diagram showing an effect of the second pulsed light in Embodiment 3.

FIG. 14 is a timing chart showing pulsed light.

FIG. 15A is a view showing a configuration of a condensing optical system of the second pulsed light.

FIG. 15B is a view showing a configuration of a condensing optical system of the second pulsed light.

### DESCRIPTION OF EMBODIMENTS

Hereinafter, embodiments of the invention will be described with reference to the drawings.

### Embodiment 1

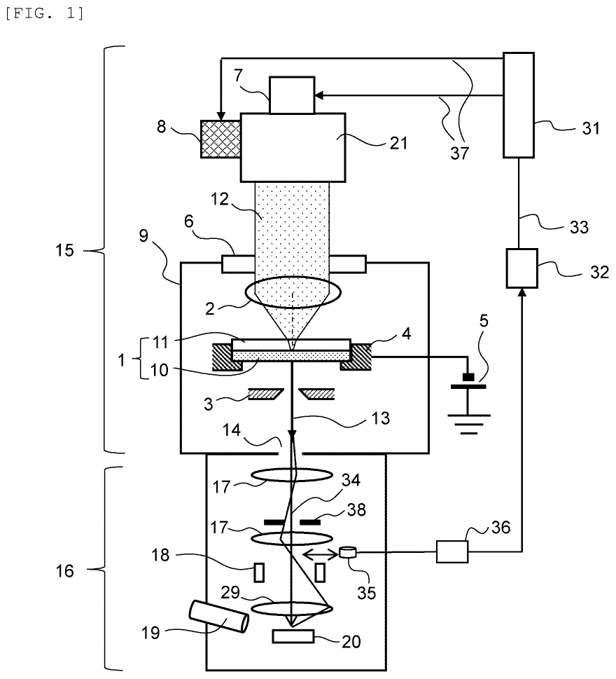

FIG. 1 is a schematic view showing an applied electron beam device. Pulsed excitation light 12 is incident onto a photocathode 1 from an upper surface, and a pulsed electron beam is generated from a lower surface of a portion where the pulsed excitation light 12 is incident. Electrons emitted from the photocathode 1 are accelerated by an electric field between opposite extraction electrodes 3, and are guided, as a pulsed electron beam 13, to an electron optical system from an opening 14 of a vacuum chamber 9. Here, a scanning electron microscope (SEM) is shown as an example of the electron optical system. The pulsed electron beam 13 extracted from the opening 14 is further reduced by two electron lenses 17 and an objective lens 29, and focused onto a sample 20. An SEM image of a sample surface is obtained from a deflector 18 for scanning a focal point position and an electron detector 19 for measuring signal electrons generated from the sample due to radiation of the pulsed electron beam 13. An aperture 38 that limits an opening angle of the electron beam is provided in a trajectory of the electron beam, and cooperates with the electron lenses 17 to perform adjustment so as to form an optimal trajectory shape.

The photocathode 1 is an electron source using a phenomenon known as negative electron affinity. A photoelectric film 10 of the photocathode 1 is a p-type semiconductor. A typical example of the photoelectric film 10 is GaAs. In order to reduce a work function, for example, Cs and oxygen are adsorbed on a surface of the photoelectric film 10.

Although not shown, a preparation chamber for this purpose is provided adjacent to an electron gun 15, and a surface of the photocathode 1 moved to the preparation chamber is adjusted. The cathode surface adjustment is performed as follows. An oxide and a carbonized material on a semiconductor surface are removed by a heater. It is more effective to generate atomic hydrogen for performing cleaning processing. Thereafter, the work function of the semiconductor surface is lowered by adsorbing Cs vaporized in an oxygen atmosphere on the semiconductor surface, and a state where a vacuum level is lower than a conductor inside a cathode film is obtained. As a result, electrons excited from a valence band to a conduction band in response to the incident of the excitation light 12 with energy sufficient for band-to-band transition in a p-type semiconductor are in a state in which potential energy is higher than that of a vacuum level, and the electrons are emitted into vacuum by an electric field on a film surface.

In the case of GaAs, a wavelength of excitation light is required to be 850 nm or less, and more preferably 780 nm to 660 nm. When electrons in the conduction band spread within the photoelectric film 10, a size of a light source increases, resulting in a decrease in luminance, which is undesirable for an electron gun used in a microscope. Therefore, a thickness of the photoelectric film 10 is required to be about 1 μm or less, and further p-type impurities are required to have a sufficient concentration. In order to support the photoelectric film 10, the photoelectric film 10 is attached to a transparent substrate 11 that does not absorb excitation light in the photocathode 1. The transparent substrate 11 of the photoelectric film 10 made of GaAs can be made of glass or a semiconductor having a wider band gap such as GaP. The photoelectric film 10 may be directly attached to the transparent substrate 11 or may be attached via an intermediate layer. When a semiconductor is used as the transparent substrate 11, the photoelectric film 10 may be formed by epitaxial growth. In this case, the photoelectric film 10 may be formed on a buffer layer that serves as an intermediate layer.

An acceleration voltage to be applied to an electron source is applied by an acceleration power source 5 via a cathode holder 4 that is in electrical contact with the photoelectric film 10, and the pulsed electron beam 13 generated from the photocathode 1 is accelerated between the extraction electrodes 3. The vacuum chamber 9 of the electron gun 15 is evacuated by a vacuum exhaust device (not shown), preferably an ion pump and a non-evaporative getter pump.

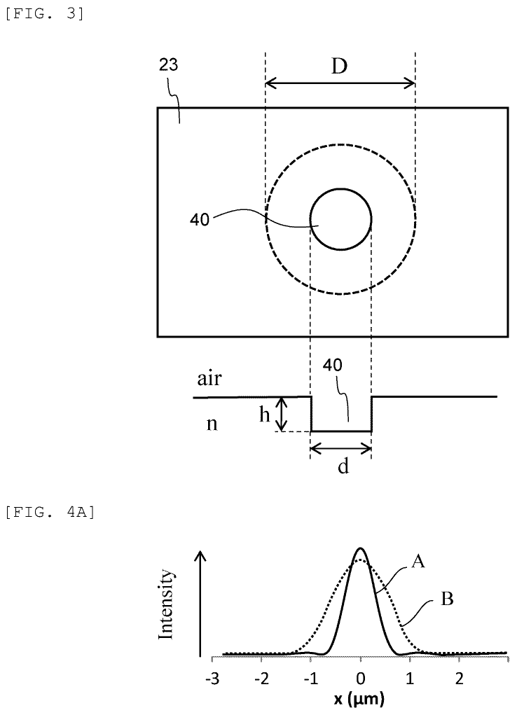

A condensing lens 2 that condenses the pulsed excitation light 12 onto the photocathode 1 is a lens for which spherical aberration is corrected to minimize a focal point formed on the photoelectric film 10 through the transparent substrate 11. In the present example, a diameter of parallel light is 4 mm to 4.2 mm, and a numerical aperture (NA) is 0.5. As a result, in the case of excitation light (laser light) having a wavelength of 660 nm, a focal point having a diameter of about 1 μm (a half width) is obtained on the photoelectric film 10 as indicated by a solid line A in FIG. 4A. The parallel pulsed excitation light 12 is emitted from a first pulsed light source 7 outside the vacuum chamber 9, and is emitted into the vacuum chamber 9 through an excitation light optical system 21 and a window 6. On the other hand, the excitation light optical system 21 is provided with a second pulsed light source 8 having a long wavelength (for example, 850 nm).

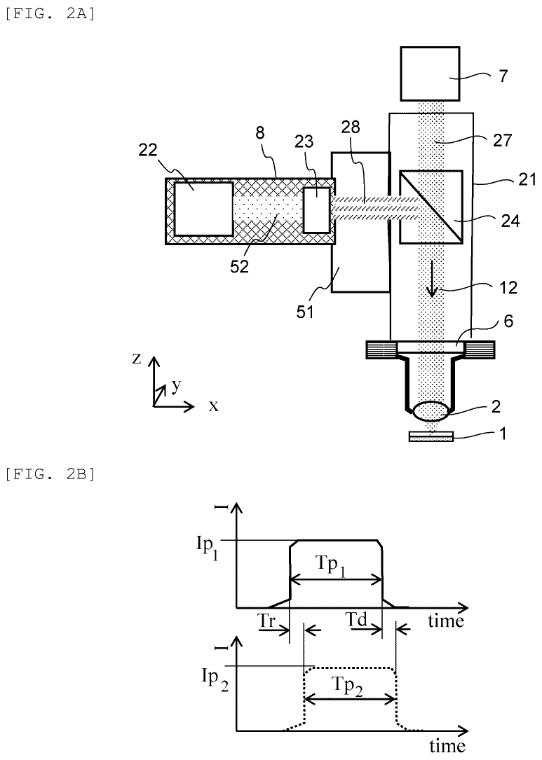

FIG. 2A shows a configuration of the excitation light optical system 21. First pulsed light 27 emitted from the first pulsed light source 7 passes through an optical coupler 24 and travels toward the photocathode 1 as the pulsed excitation light 12. Second pulsed light 28 emitted from the second pulsed light source 8 also passes along a trajectory of the pulsed excitation light 12 and is radiated to the photoelectric film 10 through the condensing lens 2. The second pulsed light source 8 is connected to the excitation light optical system 21 via a fine adjustment mount 51, and the second pulsed light 28 adjusted by the fine adjustment mount 51 is reflected toward the photocathode 1 by the optical coupler 24 and is adjusted so as to coincide with an optical path of the pulsed excitation light 12 and travel toward the photocathode. The second pulsed light 28 is laser light obtained by an optical modulator 23 modulating long-wavelength pulsed light 52 emitted from a long-wavelength pulsed light source 22 having a wavelength of 850 nm.

FIG. 3 shows an example in which a phase mask having a phase difference between a center and an outer periphery of laser light is used as an example in the modulation performed by the optical modulator 23. FIG. 3 shows a plan view and a cross-sectional structure of a center portion of the phase mask used as the optical modulator 23. The optical modulator 23 is a transparent plate having a refractive index n for the wavelength of the second pulsed light 28. A circular phase shift region 40 is provided in the center of the optical modulator 23. There is a step between the phase shift region 40 and a peripheral region. As a result, a phase of a center portion and a phase of an outer peripheral portion of the obtained second pulsed light 28 are shifted by r, and a light intensity distribution of light on the photoelectric film 10 through the condensing lens 2 has a ring shape having a dark center as shown in FIG. 4B.

Since light phases are shifted by n due to the phase shift region 40, a height h (see FIG. 3) of the step of the phase shift region 40 is required to satisfy Formula 1.

$$h = λ / ( 2 ( n - 1 ) ) \qquad [ Formula 1 ]$$

When the optical modulator 23 is made of a quartz plate (n=1.46) and the wavelength of the second pulsed light 28 is 850 nm, h=924 nm. In order to minimize the light intensity in the center portion, that is, to make the light intensity distribution into a ring shape, a diameter d (see FIG. 3) of the phase shift region 40 is set to a size determined according to (Formula 2).

$$d = D / \sqrt{2} \qquad [ Formula 2 ]$$

Here, D (see FIG. 3) is a diameter of the second pulsed light 28. Formula 2 is a condition when a light intensity of the second pulsed light 28 is uniform. For example, when the second pulsed light 28 has an intensity distribution like a Gaussian beam, the diameter d is required to be set accordingly.

It should be noted that the wavelength of 850 nm of the second pulsed light 28 is an example, and the wavelength of the second pulsed light 28 is determined so as to be substantially the same as band gap energy of a semiconductor GaAs constituting the photoelectric film 10. Any wavelength that causes stimulated emission to recombine excited electrons in the photoelectric film 10 is acceptable. Therefore, when the photoelectric film 10 is made of a crystal other than GaAs, the wavelength is determined by physical properties of the crystal, and when the photoelectric film 10 has a superlattice structure, the wavelength corresponds to gap energy of a formed miniband. In this case, a condition is that the wavelength is a wavelength at which the photoelectric film 10 causes stimulated emission.

The optical coupler 24 that combines an optical path of the first pulsed light 27 and an optical path of the second pulsed light 28 may be a half mirror, a polarized beam splitter, a dichroic mirror, or the like. When a dichroic mirror is used as the optical coupler 24, the first pulsed light 27 is transmitted, the second pulsed light 28 is reflected, and the first pulsed light 27 and the second pulsed light enter a trajectory of the pulsed excitation light 12. In such a case, a system with little light loss can be achieved.

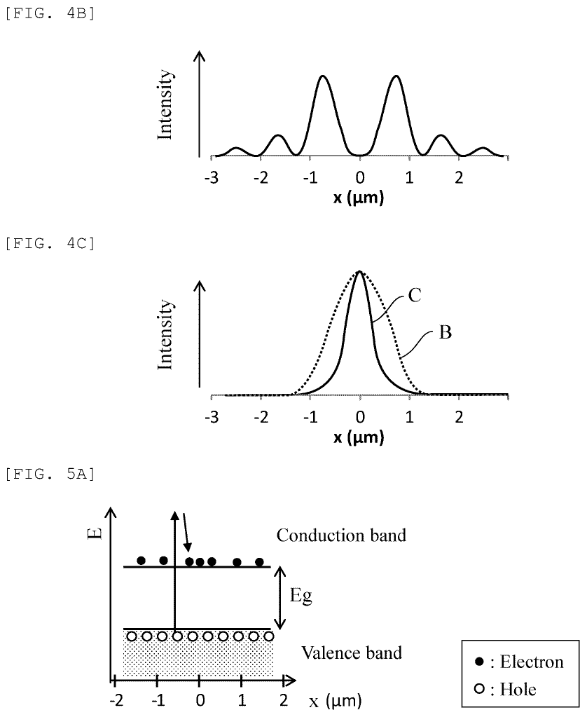

An effect of irradiating the photoelectric film 10 with the first pulsed light 27 and the second pulsed light 28 that is spatially modulated will be described. FIG. 5A shows a state in which electrons in a valence band are excited in a conduction band beyond an energy gap Eg in the photoelectric film 10 in response to the incidence of the first pulsed light 27, and energy is lost due to phonon scattering or the like and the electrons are temporarily accumulated at the bottom of the conduction band. A spatial distribution of the electrons in the conduction band at this time is indicated by a broken line B in FIG. 4A. As compared with the intensity distribution of the first pulsed light 27 indicated by the solid line A in FIG. 4A, the spatial distribution of the electrons has a spread of about 1.5 μm at a half width due to scattering or diffusion of electrons. Since the electrons are emitted into vacuum, a source size of an electron beam is larger than an intensity distribution of excitation light and is about 1.5 μm at a half width.

When the second pulsed light 28 is incident by optimizing a pulse intensity (a height), a pulse width, and a timing in the state shown in FIG. 5A, as shown in FIG. 5B, at a portion where the second pulsed light 28 is radiated, electrons in the conduction band and holes in the valence band are immediately recombined to emit light, resulting in stimulated emission. Since the light intensity distribution of the second pulsed light 28 has a ring shape with a weak center portion as shown in FIG. 4B, a distribution of the electrons in the conduction band becomes a solid line C from a broken line B as shown in FIG. 4C, and can be narrowed to 1 μm or less at a half width. Since electrons corresponding to the spread of the solid line C are emitted into vacuum, a source size of an electron beam can be narrowed to about 0.8 μm at a half width.

In an electron source using negative electron affinity, it is fairly effective to reduce a region for emitting electrons to increase luminance of an electron beam. Even when an area of an emission region is large, if a current density of emitted electrons is the same, it is theoretically possible to increase luminance. High luminance condition requires a large current density of several A/mm². For example, when a size of the emission region is 1 mm² at a certain current density, a large current of several A is required. In this case, side effects such as melting of a photoelectric film of GaAs due to heat generation, Cs evaporation, or accumulation of surface charges on a photoelectric film surface occur, which makes it difficult to sustain electron emission. In order to avoid such side effects, it is necessary to reduce a total current amount by reducing an area of the electron emission region as much as possible.

In the related art, by using an aspherical lens as the condensing lens 2 and narrowing down excitation light to a diffraction limit, an intensity distribution having a diameter of about 1.2 μm to 1.5 μm can be obtained. On the other hand, by using the second pulsed light 28, the electron emission region can be reduced by 67% to 53%, and an area can be reduced by 44% to 28%, so that for the same total current, luminance can be increased by two to three times.

In this manner, a part outside the electrons in the conduction band generated in the photoelectric film 10 due to the first pulsed light 27 is eliminated by the second pulsed light 28, thereby generating a high-luminance electron beam. The second pulsed light 28 has an effect of recombining excited electrons with holes caused by stimulated emission, and also has an effect of exciting electrons in a valence band to a conduction band. Therefore, it is necessary to optimize an intensity and a timing of both pulsed light so that the second pulsed light 28 is used substantially for stimulated emission.

An adjustment unit for both pulsed light will be described. In FIG. 2B, a vertical axis represents an intensity I, and a horizontal axis represents a time. FIG. 2B shows time changes of intensities of both pulsed light. A pulse of the first pulsed light 27 is indicated by an intensity Ip₁ and a pulse width Tp₁. The pulse width Tp₁ is a time that can be selected according to purpose of an experiment. A feature value is 1 picosecond or more, and can also be a nanosecond or microsecond order. The intensity Ip₁ is set according to required luminance of an electron gun. On the other hand, a pulse of the second pulsed light 28 is indicated by an intensity Ip₂ and a pulse width Tp₂. A start delay time Tr of the second pulsed light 28 from the start of the first pulsed light 27 and an end delay time Td of the second pulsed light 28 from the end of the first pulsed light 27 for determining the pulse width Tp₂ are optimized by preliminary experiments.

In order to achieve this, as shown in FIG. 1, a control signal 33 indicating a height and a timing of each pulse is sent from a main body control device 32 to an excitation light control device 31. The excitation light control device 31 issues a laser control signal 37 to each of the first pulsed light source 7 and the second pulsed light source 8 to adjust a timing and an intensity.

For magnitudes of the start delay time Tr and the end delay time Td, in principle, electrons generated in the conduction band by the first pulsed light 27 lose energy due to phonon scattering on the order of femtoseconds and are accumulated at the bottom of the conduction band, but thereafter, the electrons are recombines with holes and disappear in about 1 picosecond. Therefore, the start delay time Tr is selected from 0 picoseconds to 0.1 picoseconds, and the end delay time Td is selected from 0 picoseconds to 1 picoseconds. In order to optimize the start delay time Tr and the end delay time Td, luminance of a pulsed electron beam is monitored and adjusted to highest luminance. Luminance of the pulsed electron beam 13 can be grasped from resolution and brightness of an SEM image obtained by an electron optical system. Further, it is possible to more easily grasp the luminance of the pulsed electron beam 13 by inserting a Faraday cup 35 into a central axis 34 of the electron optical system and measuring a probe current by a current detector 36. As will be described later, since the electron beam reduced by a plurality of the electron lenses 17 passes through the aperture 38 with a reduced current amount for limiting an opening angle, an insertion position of the Faraday cup 35 needs to be closer to the sample 20 than the aperture 38. Luminance information obtained in this manner is fed back to the main body control device 32 in order to optimize conditions of the electron gun 15.

Higher resolution observation can be achieved by using the pulsed electron beam 13 with increased luminance as described above in a scanning electron microscope. Alternatively, since the probe current can be increased even with the same resolution as that of a device in the related art, high-speed observation can be achieved. In particular, an energy distribution of an electron source in the present embodiment is 0.1 eV to 0.2 eV, which is more consistent than 0.3 eV of a cold electric field emission (CFE) electron source using a tungsten filament and 0.8 eV of a Schottky emission (SE) electron source, and therefore it is possible to improve resolution by reducing chromatic aberration, especially at low acceleration. For example, when the acceleration power source 5 is set to −2 kV, the electron beam 13 emitted from the electron gun has a radiation angle current density of 39 mA/sr or more.

In order to obtain an electron light source diameter of 800 nm that is smaller than that of the configuration in Embodiment 1 and enable observation with resolution of 1 nm or less, when a size of an electron beam probe formed on a sample is set to 0.8 nm or less, a total reduction ratio by the electron lenses 17 and the objective lens 29 in an electron optical system housing 16 may be set to about 1/1000. For example, when the aperture 38 and an optical condition are adjusted such that an opening half angle αo of the objective lens 29 toward the sample 20 is 10 mrad, an electron beam that can pass through the aperture 38 has a beam divergence half angle as on a light source side of the electron gun 15 in fairly narrow range of 5 μrad or less. In this case, a probe current of electrons radiated onto the sample 20 is about 10 pA, and can be observed with high sensitivity and short time. A depth of a focal point, expressed as spot diameter/αo, is about 100 nm.

Since the electron beam 13 is a pulsed electron beam, the electron beam 13 is also useful for time-resolved measurement.

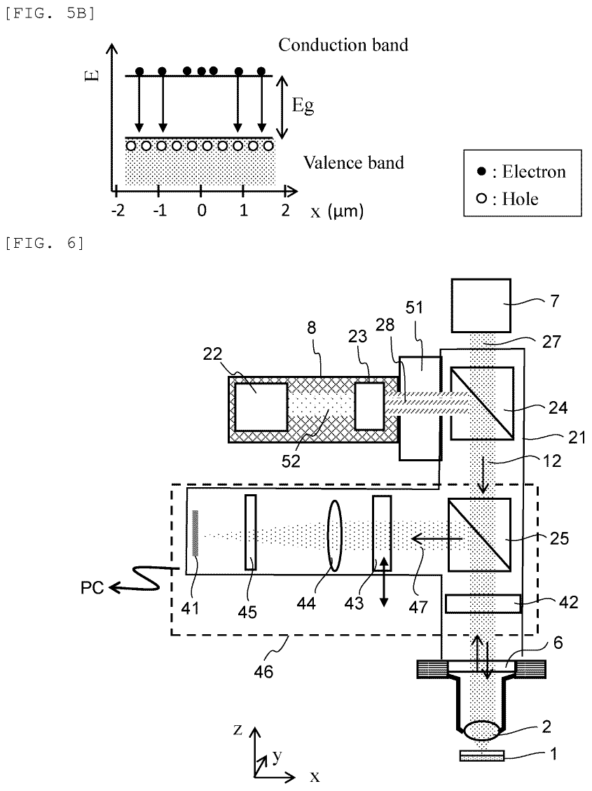

FIG. 6 shows a modification of the excitation light optical system 21. The excitation light optical system 21 shown in FIG. 6 includes a monitor optical system 46 that measures reflected light 47 from the photocathode 1 for facilitating optimization of the excitation light optical system 21. A reflected light separator 25 for separating the reflected light 47 in a lateral direction (an x direction) is provided in an optical path. Here, for example, a polarized beam splitter (PBS) is used as the reflected light separator 25, and a ¼ wavelength plate 42 is provided below the reflected light separator 25. The pulsed excitation light 12 that passes through the reflected light separator 25 is linearly polarized light having an electric field component parallel to a paper surface, and becomes circularly polarized light when the linearly polarized light passes through the ¼ wavelength plate 42. The circularly polarized light that is reflected from the photocathode 1 and passes through the condensing lens 2 is converted into linearly polarized light having an electric field component perpendicular to the paper surface when the circularly polarized light passes through the ¼ wavelength plate from bottom to top. Therefore, the linearly polarized light is reflected by the reflected light separator (PBS) 25, and only the reflected light 47 from the photocathode 1 is introduced into the monitor optical system 46. The reflected light 47 is imaged on an imaging element 41 by an image forming optical system including an image forming lens 44, so that a condensing position and a focal point shape of excitation light on the photocathode 1 can be observed in a magnified manner. Based on the observed condensing position and focal point shape of the excitation light, optical paths of the first pulsed light 27 and the second pulsed light 28 are adjusted so that focal point positions of the first pulsed light 27 and the second pulsed light 28 coincide with each other. In the present configuration example, the optical path of the second pulsed light 28 is aligned with the optical path of the first pulsed light 27 by adjusting a position and an angle of the second pulsed light source 8 by the fine adjustment mount 51. Further, the monitor optical system 46 is provided with a light reducing unit such as an ND filter 45 in order to optimize an amount of light observed by the imaging element 41.

Further, a removable polarizer 43 may be provided in the monitor optical system 46. By inserting the polarizer 43, the reflected light 47 which is linearly polarized light cannot pass through the polarizer 43. On the other hand, since stimulated emission light obtained in response to the incidence of the first pulsed light 27 and the second pulsed light 28 is circularly polarized light, light obtained by stimulated emission can be observed on the imaging element 41. Incident positions of the first pulsed light 27 and the second pulsed light 28 can be adjusted by an intensity and a shape of the light obtained by stimulated emission. For example, a polarizer capable of switching a polarization direction of light that can pass through the polarizer may be used.

Hereinafter, details of a modification will be described.

In order to adjust a timing, an optical signal may be used as the laser control signal 37 from the excitation light control device 31 shown in FIG. 1 to the first pulsed light source 7 and the second pulsed light source 8. In the case of an optical signal, the timing can be adjusted by using a device that sets a delay time of light transmission by adjusting an optical path length, which is called optical delay, and the optical signal is advantageous in adjusting a minute time.

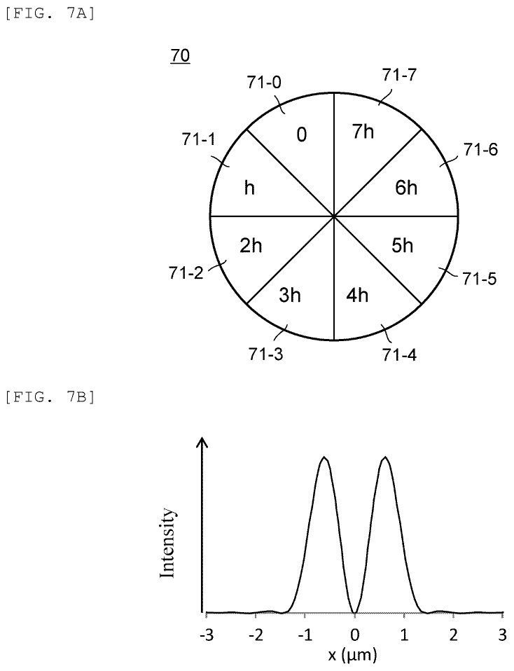

The optical modulator 23 is not limited to that shown in FIG. 3, and a spatial phase modulator such as a liquid crystal element may be used. Further, a spiral phase plate shown in FIG. 7A may be used as a phase modulator in which a center portion has a dark donut-shaped focal point shape on the photocathode 1. A spiral phase plate 70 has a circular shape, and in the present example, the spiral phase plate 70 is divided into eight in a circumferential direction, and a height is changed counterclockwise from a divided region 71-0 to a divided region 71-7. A phase changes by π/4 in each stage. A height h of a step between divided regions adjacent to each other in the counterclockwise direction is obtained according to (Formula 3).

$$h = λ / ( 8 ( n - 1 ) ) \qquad [ Formula 3 ]$$

The second pulsed light 28 that passed through the spiral phase plate has a helical polarization, and is focused to form a light intensity pattern on the photocathode 1 as shown in FIG. 7B. A width of a central dark portion can be made narrower than that in the case of a phase plate having the structure shown in FIG. 3. When the spiral phase plate is used, since an emission source of an electron beam having a narrower diameter of 0.5 μm can be used, luminance of the electron beam can be four times or more by adjusting the electron beam with the first pulsed light 27. The spiral phase plate may have a structure in which the spiral phase plate is divided into eight or more or the height is changed continuously, and the same effect can be obtained when a phase difference is 2π over one circumference.

The photoelectric film 10 is not limited to GaAs, and other materials that cause electron emission using negative electron affinity may be used. For example, GaP, mixed crystals such as GaAs—GaP and GaAs—AlAs, or superlattice may be used. As described above, a wavelength of the second pulsed light 28 needs to be selected according to a material and a structure of the photoelectric film 10.

Pulse widths of the first pulsed light 27 and the second pulsed light 28 in the present embodiment are typically selected from 1 picosecond to 1 μsecond. However, it is possible to widen a pulse width that can be used by adjusting a light intensity. For example, light may be continuous light with a duration width from milliseconds to several tens of seconds or more depending on an observation time of an electron microscope.

Depending on an applied electron beam device, a light source size of an electron beam may be reduced only in use time to increase luminance. In this case, either the first pulsed light 27 or the second pulsed light 28 may be pulsed light, and the other one may be continuous light.

### Embodiment 2

In the present embodiment, infrared light is used in the second pulsed light source 8 in the configuration of the applied electron beam device shown in FIG. 1. A wavelength of the infrared light does not cause band-to-band transition in the photoelectric film 10, but the infrared light has energy for exciting electrons from a valence band to an acceptor level and generating holes (positive holes).

A wide gap semiconductor such as GaN and diamond has a much larger dielectric breakdown electric field than a semiconductor such as Si and GaAs. As a result, the wide gap semiconductor can transport large amounts of electrons in a bulk, and thus the wide gap semiconductor is a fairly desired electron source that requires a large current density. However, when electrons are emitted from GaN-based or GaInN-based superlattice or mixed crystals due to negative electron affinity, a current density cannot be increased. This is because p-type doping does not work well.

For example, when a semiconductor such as Si is doped with an impurity that acts as an acceptor, energy Ea from a valence band of an acceptor level that occurs in a forbidden band is small at 0.05 eV, and even at room temperature, electrons enter an acceptor due to thermal energy, making it negatively charged, and holes are generated in the valence band due to loss of electrons. The holes can move around as charge carriers, thereby increasing electrical conductivity and minimizing a width of a depletion layer that can be formed near a surface by performing redistribution to mitigate an electric field from the outside. On the other hand, in the case of a wide gap material, the energy Ea of the acceptor level is about 0.1 eV for GaN and about 0.5 eV for diamond, and a hole density cannot be increased by thermal excitation at room temperature. Although there is no definite definition for band gap energy Eg required to classify a semiconductor into the wide gap semiconductor, here, a semiconductor having a band gap energy Eg of 3 eV or more is used as the wide gap semiconductor.

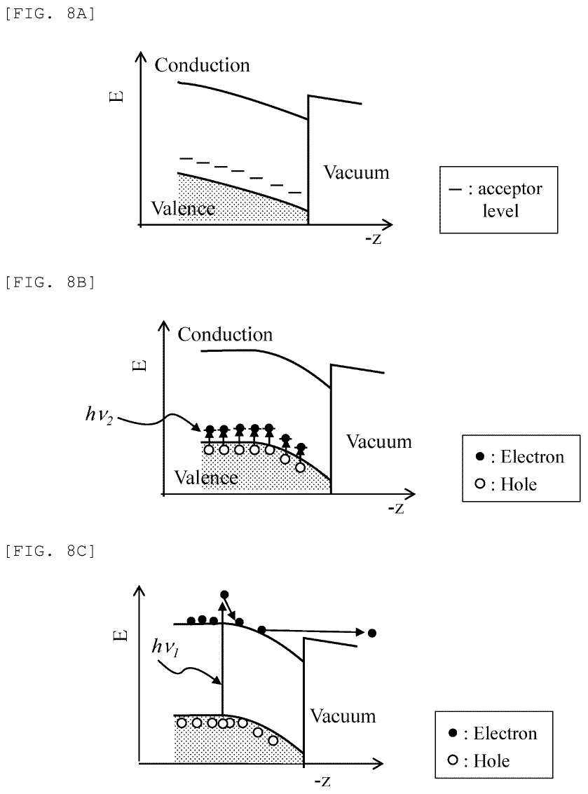

FIGS. 8A to 8C show models of an energy structure of a GaN-based wide gap semiconductor doped with a p-type impurity, which are used as the photoelectric film 10. FIG. 8A shows a model when no light is radiated in a state where Cs or oxygen are adsorbed on a surface of the photoelectric film 10 and the work function is lowered in vacuum. Since an acceptor is almost not charged and a hole density is low, there is no charge carrier, and a vicinity of the surface is depleted due to a difference between an internal potential and a surface potential. Even when electrons and holes are generated due to band-to-band transition in response to radiation of excitation light, since there is almost no charge carrier, an emission current density does not become sufficiently large due to an attractive force between the electrons and the holes and an increase in the potential due to charges accumulated on the surface, and luminance of an electron source is fairly low.

In this state, the second pulsed light which is infrared light is radiated. Energy hv₂ of the second pulsed light is equal to or higher than the energy Ea of the acceptor level, and holes are generated as a result of charging an acceptor by electrons in the valence band as shown in FIG. 8B. Note that h is a Planck constant, and v₂ is a frequency of the second pulsed light. As a result, an electric field inside holes with a high density is reduced, and a very narrow depletion layer is formed on the surface. In this state, when the first pulsed light 27 having energy hv₁ (v₁ is a frequency of the first pulsed light 27) is incident, electrons excited in a conduction band due to band-to-band transition as shown in FIG. 8C are emitted into the vacuum at a high density.

A wavelength of the second pulsed light is set such that the second pulsed light has energy sufficiently lower than the band gap energy and equal to or higher than the energy Ea of the acceptor level, and may be determined for each band gap energy, such as a wavelength of 1 μm or more, a long wavelength limit of 12 μm for GaN, and 2.45 μm for diamond.

Continuous radiation of the infrared light that generates holes causes a rise in the temperature of the photoelectric film 10, which can lead to Cs evaporation and deterioration of crystals, making it impossible to stably emit electrons as an electron source. Therefore, it is effective to radiate the infrared light in synchronization with the first pulsed light 27, and a timing is set such that the infrared light is radiated at the same time with or slightly prior to the radiation of the first pulsed light 27. This relationship is shown in FIG. 9. A vertical axis represents an intensity I, and a horizontal axis represents a time. FIG. 9 shows time changes of intensities of both pulsed light. A pulse of the first pulsed light 27 is indicated by an intensity Ip₁, a pulse width Tp₁, and a pulse of the second pulsed light is indicated by an intensity Ip₂ and a pulse width Tp₂. A preceding time −Tr of a rising edge of the second pulsed light relative to a rising edge of the first pulsed light 27 and a preceding time −Td of a falling edge of the second pulsed light relative to a falling edge of the first pulsed light 27 are optimized in a range of about 0 picoseconds to several picoseconds, and in order to obtain maximum luminance, the preceding time −Tr and the preceding time −Td, and the intensities Ip₁ and Ip₂ are determined by feeding back information such as a probe current amount and resolution of the electron optical system as in Embodiment 1.

A wide gap material of the photoelectric film 10 is not limited to GaN or diamond, and may be mixed crystals such as AlGaN and GaInN, or superlattice of the mixed crystals with GaN or the like.

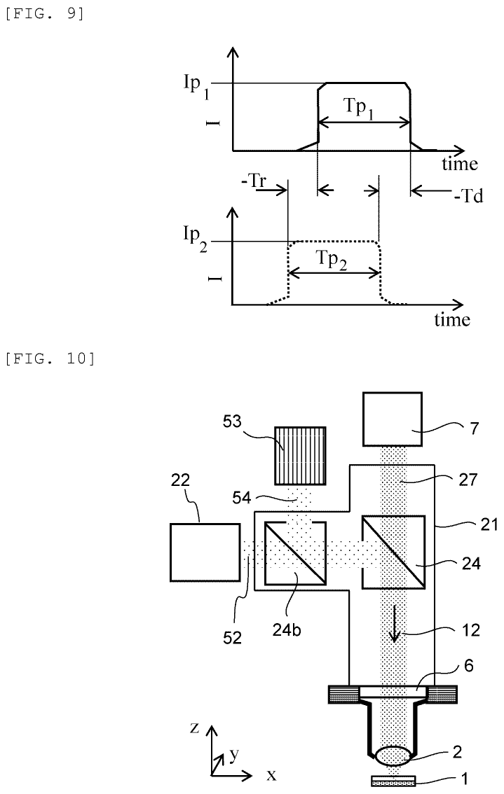

Here, light for generating holes may be a combination of light beams having two wavelengths, instead of directly radiating infrared light having a long wavelength onto a condensing position of the first pulsed light 27 on the photocathode (in this case, since there is no need to combine the optical path of the first pulsed light 27 and the optical path of the second pulsed light, the excitation light optical system 21 can be omitted). FIG. 10 shows a configuration example of the excitation light optical system 21 in this case. An optical coupler 24b makes an optical path of third pulsed light 54 from a third pulsed light source 53 to coincide with the optical path of the second pulsed light 52 emitted from the second pulsed light source 22, and irradiates the photocathode 1 with the second pulsed light 52 and the third pulsed light 54. Wavelengths of the second pulsed light 52 and the third pulsed light 54 are long wavelengths at which light does not cause band-to-band transition in the photoelectric film 10, and an energy difference between the second pulsed light 52 and the third pulsed light 54 is equal to or larger than the energy Ea of the acceptor level. In this configuration, since visible light or near-infrared light can be used as the second pulsed light 52 and the third pulsed light 54, an refractive index of the condensing lens 2 can be used under near ideal conditions. Therefore, as compared with the case of directly radiating the infrared light, a hole density can be increased while a range in which the temperature rises due to radiation of light is minimized only in the vicinity of an electron emission source. Since it is possible to resonantly charge an acceptor and generate holes, there is an advantage that a scattering cross section increases and efficiency increases.

When the second pulsed light 52 and the third pulsed light 54 are radiated at the same time, the band-to-band transition may occur in two-photon absorption. In order to prevent the band-to-band transition, energy of each of the second pulsed light 52 and the third pulsed light 54 is preferably ½ or less of the band gap energy Eg. Further, in order to obtain maximum luminance, intensities of the second pulsed light 52 and the third pulsed light 54 and radiation timings of the second pulsed light 52 and the third pulsed light 54 relative to a radiation timing of the first pulsed light 27 are determined by feeding back information such as a probe current amount and resolution of the electron optical system as in Embodiment 1.

The radiation of the infrared light has an effect of increasing the luminance for not only the photoelectric film including a wide gap semiconductor but also the photoelectric film 10 having the band gap energy Eg of around 1 eV, such as GaAs.

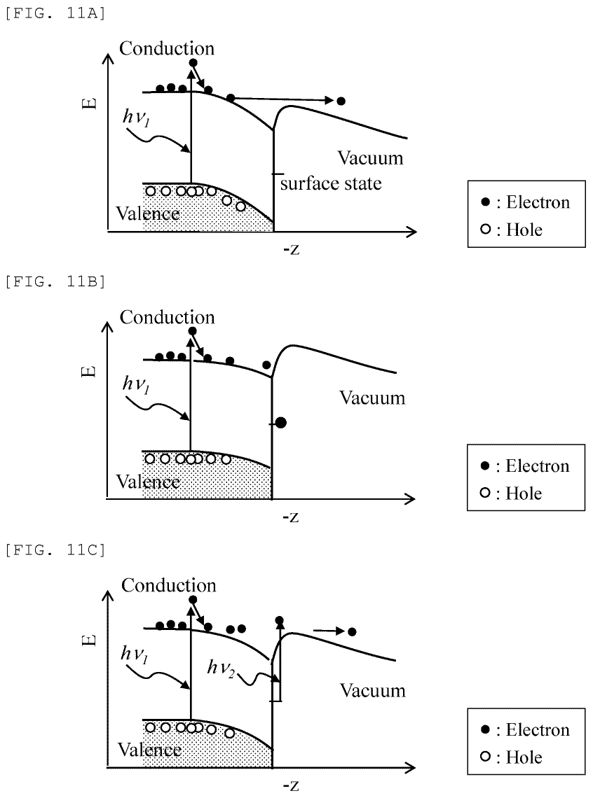

When GaAs or the photoelectric film 10 mainly made of GaAs is used as an electron source using negative electron affinity, in an initial stage of electron emission, as shown in FIG. 11A, an intensity of electrons excited in the conduction band by photoexcitation with the energy hv₁ in response to incidence of the first pulsed light 27 exceeds a lowered vacuum level, and the electrons are emitted into the vacuum. However, over time, electrons scattered inside the surface are trapped in a level at which the electrons are difficult to escape, such as a surface state. FIG. 11B shows a state in which electrons are trapped in the surface state, which increases electron potential energy on the surface of the photoelectric film 10, thereby reducing an amount of electron emission. This is one reason for limiting luminance.

Therefore, by radiating the second pulsd light which is infrared light, electrons trapped in the surface state are excited by light to the conduction band or the vacuum level as shown in FIG. 11C and are removed, and thus it is possible to prevent a decrease in luminance. The potential energy of the surface state is near the center of the forbidden band, and in the case of GaAs, the potential energy is about 0.7 eV which is half of the band gap energy Eg. Therefore, when the energy hv₂ of the second pulsed light is 0.7 eV or more and less than 1.4 eV, electrons trapped in the surface state are excited and removed by drift and diffusion in a solid, or are emitted into the vacuum, so that electron emission continues, and high luminance is achieved.

A timing of the second pulsed light relative to the first pulsed light 27 in this case may be adjusted so as to radiate the first pulsed light 27 and the second pulsed light at the same time or to slightly delay a radiation timing of the second pulsed light as shown in FIG. 2B.

### Embodiment 3

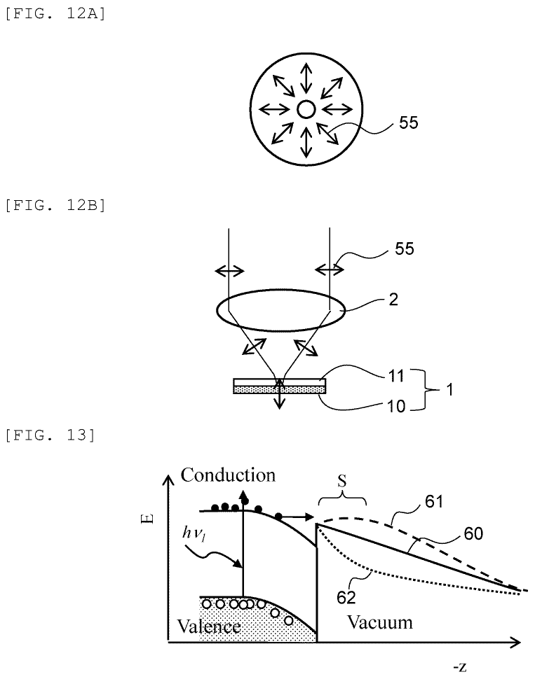

In the present embodiment, long-wavelength light that is radially polarized light is used as the second pulsed light in the configuration of the applied electron beam device shown in FIG. 1. Therefore, a light source that emits a long-wavelength radially polarized beam is used as the second pulsed light source 8. In the radially polarized beam, as shown in FIG. 12A, an electric field orientation 55 of light in a cross section of parallel light is a radiation shape, and at a focal point formed on the photocathode 1 by the condensing lens 2, the electric field orientation is perpendicular to the surface of the photoelectric film 10 as shown in FIG. 12B.

Various techniques have been developed in such a radially polarized light generation method. For example, it is possible to convert linearly polarized light by using a spatially-variant waveplate or a conical Brewster prism. In the second pulsed light source 8, these optical elements may be used instead of the optical modulator 23. In addition, it is also possible to generate radially polarized light by a method of applying a pulse voltage to an antenna of a fine structure pattern or the like.

FIG. 13 shows an energy model of irradiating the photoelectric film 10 with a radially polarized beam in a state in which the photoelectric film 10 is irradiated with the first pulsed light 27 to cause electron emission. When the second pulsed light is not radiated, a vacuum level 60 is uniformly changed relative to a distance z. This is because an electric field is applied between the photocathode 1 and the extraction electrode 3 due to a potential difference therebetween (see FIG. 1). When electrons are emitted from the photoelectric film 10 in this state, a speed of the emitted electrons is small in a very close vicinity of the surface of the photoelectric film 10 shown as a region S in FIG. 13. Therefore, when an intensity of the emitted electrons is increased, the speed of the electrons is slow. Therefore, in the region S, electrons emitted earlier hinder emission of electrons emitted later, and a Coulomb force between electrons emitted earlier and electrons emitted later causes a phenomenon in which an energy width increases or a trajectory expands in a lateral direction. This effect is called a space charge effect, and the space charge effect limits luminance of an electron source that emits electrons into the vacuum, and widens an energy distribution, resulting in deterioration of quality of an electron beam used in an electron microscope.

On the other hand, when the radially polarized second pulsed light is focused and radiated, as shown in FIG. 13, a state is obtained in which a vacuum level 61 (indicated by a broken line) superimposed with a negative electric field relative to the surface and a vacuum level 62 (indicated by a dotted line) superimposed with a positive electric field relative to the surface oscillate over time. In order to reduce the space charge effect, electrons in the region S may be accelerated in a shorter time. That is, it is preferable to irradiate the photoelectric film 10 with the first pulsed light 27 at a timing when the photoelectric film 10 is in a state of the vacuum level 62 superimposed with a positive electric field, thereby causing electrons to be emitted from the photoelectric film 10.

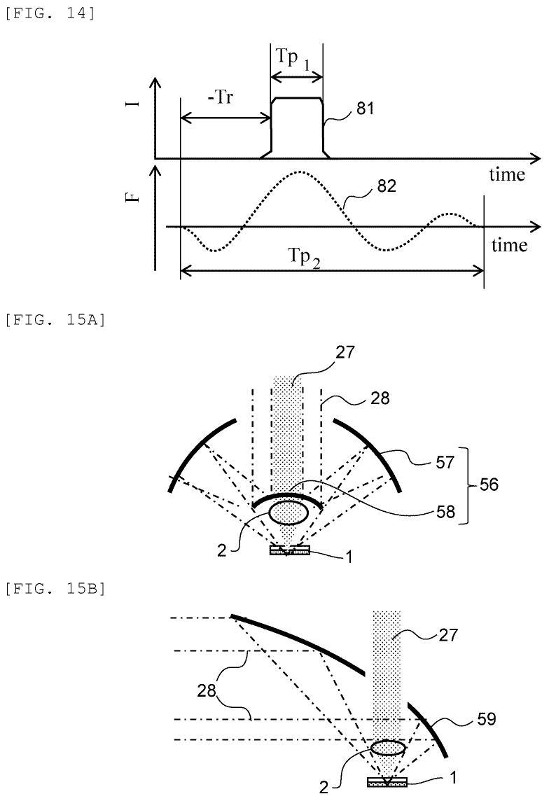

FIG. 14 shows radiation timings of the first pulsed light 27 and the second pulsed light. A waveform 81 represents an intensity I of the first pulsed light 27, and a waveform 82 represents changes over time of an electric field F on the surface of the photoelectric film 10 caused by the second pulsed light. As described above, the space charge effect can be reduced by irradiating the photoelectric film 10 with the first pulsed light 27 in a time zone in which the electric field F is positive due to the second pulsed light, and the luminance of the photoelectric film 10 can be increased. When a pulse width Tp₁ of the first pulsed light is 1 picosecond, a time of a portion where an oscillating electric field of the second pulsed light is required to be larger than 1 picosecond. For example, when an oscillating period is 2 picoseconds, a frequency is 0.5 THz and a wavelength is 600 μm. A pulse width Tp₂ of the second pulsed light is several picoseconds, and a preceding time −Tr of a rising edge of the second pulsed light relative to a rising edge of the first pulsed light 27 is also about several picoseconds. A magnitude of the preceding time −Tr is optimized based on a luminance measurement result in the electron optical system as in Embodiment 1.

When a time of the pulse width of the first pulsed light 27 is shortened, the frequency of the second pulsed light is selected to be on an order of terahertz. For example, when the pulse width of the first pulsed light 27 is 0.1 picoseconds, the wavelength of the second pulsed light is 60 μm or more.

In this manner, since electrons are emitted at a timing when a positive electric field is superimposed in the present embodiment, as shown in FIG. 13, electrons are accelerated by the vacuum level 62 superimposed with the positive electric field. Since energy of electrons in the vacuum is conserved, even when the acceleration differs slightly depending on an electric field that changes over time, electrons emitted from the same potential energy will reach a fixed speed when sufficiently far away from the photoelectric film 10. This is advantageous in that energy spread of an electron beam emitted from an electron source is kept narrow when the electron beam is guided to an electron optical system, so that it is possible to improve resolution by reducing chromatic aberration and enable an experiment in which a short pulse is used.

FIGS. 15A and 15B show examples of a suitable focusing optical system for the second pulsed light in the present embodiment. The first pulsed light 27 is condensed toward the photocathode 1 by the condensing lens 2. On the other hand, since a refractive index has wavelength dependence, when the wavelength of the second pulsed light is too long for the condensing lens 2, the second pulsed light may not be sufficiently condensed by the condensing lens 2. In such a case, it is effective to use a mirror having a small wavelength dependence of light. For example, as illustrated in FIG. 15A, a reflective objective lens 56 using a mirror may be used. The second pulsed light passes through a hole formed in an upper portion of a concave mirror 57, is reflected by a convex mirror 58, and is condensed on the photocathode 1 by the concave mirror 57. A dichroic mirror is used as the convex mirror 58 so that the first pulsed light 27 can pass therethrough.

Alternatively, as illustrated in FIG. 15B, the second pulsed light may be introduced from a direction different from that of the first pulsed light 27 and condensed by a parabolic mirror 59 or the like (in this case, since the optical path of the first pulsed light 27 and the optical path of the second pulsed light do not need to be combined, the excitation light optical system 21 can be omitted). As shown in FIG. 15B, when the second pulsed light is a parallel beam, the parabolic mirror 59 is used, whereas when the second pulsed light is a diverging beam from a small point light source, an ellipsoidal mirror may be used.

Condensing of the second pulsed light by a mirror may be performed by disposing the mirror on a lower surface of the photocathode 1, that is, on an opposite side to the condensing lens 2 with the photocathode 1 interposed therebetween. Further, the reflective objective lens 56 and the parabolic mirror 59 may be used to focus the first pulsed light 27.

The photoelectric film 10 of the photocathode 1 is not limited to GaAs, and may be GaP, AlGaAs, GaN, InGaN, and the like, and a metal film such as gold can also reduce the space charge effect during electron emission.

Although the invention is specifically described based on the embodiments, the invention is not limited to the embodiments, and various modifications can be made without departing from the gist of the invention. It is also effective to appropriately apply the embodiments in combination rather than alone. Although a scanning electron microscope is described as an example of the applied electron beam device, the invention can be applied to various applied electron beam devices such as a transmission electron microscope and a scanning transmission electron microscope. The invention is not limited to an applied electron beam device including an electron detector that detects electrons (secondary electrons, reflected electrons, and the like) generated in response to radiation of an electron beam, and may include another detector such as a detector that detects characteristic X-rays. In any case, it is possible to achieve higher resolution of a microscope image, faster measurement, and more advanced functionality by obtaining a pulsed electron beam with high luminance.

### REFERENCE SIGNS LIST

1: photocathode
2: condensing lens
3: extraction electrode
4: cathode holder
5: acceleration power source
6: window
7: first pulsed light source
8: second pulsed light source
9: vacuum chamber
10: photoelectric film
11: transparent substrate
12: pulsed excitation light
13: pulsed electron beam
14: opening
15: electron gun
16: electron optical system housing
17: electron lens
18: deflector
19: electron detector
20: sample
21: excitation light optical system
22: long-wavelength pulsed light source
23: optical modulator
24, 24b: optical coupler
25: reflected light separator
27: first pulsed light
28: second pulsed light
29: objective lens
31: excitation light control device
32: main body control device
33: control signal
34: central axis
35: Faraday cup
36: current detector
37: laser control signal
38: aperture
40: phase shift region
41: imaging element
42: ¼ wavelength plate
43: polarizer
44: image forming lens
45: ND filter
46: monitor optical system
47: reflected light
51: fine adjustment mount
52: long-wavelength pulsed light
53: third pulsed light source
54: third pulsed light
55: electric field orientation
56: reflective objective lens
57: concave mirror
58: convex mirror
59: parabolic mirror
60, 61, 62: vacuum level
70: spiral phase plate
71-0 to 71-7: divided region
81, 82: waveform

1. An applied electron beam device comprising:
a photocathode including a photoelectric film;
a first pulsed light source configured to emit first pulsed light;
a second pulsed light source configured to emit second pulsed light having a longer wavelength than the first pulsed light and having a ring-shaped light intensity distribution;
an excitation light optical system configured to emit the first pulsed light and the second pulsed light in a manner of combining an optical path of the first pulsed light and an optical path of the second pulsed light;
a condensing lens configured to condense, on the photocathode, the first pulsed light and the second pulsed light that are emitted from the excitation light optical system; and
an electron optical system configured to irradiate a sample with an electron beam emitted from the photocathode.

2. The applied electron beam device according to claim 1, wherein
the wavelength of the second pulsed light is a wavelength at which electrons excited in the photoelectric film are recombined with holes due to stimulated emission.

3. The applied electron beam device according to claim 1, wherein
the second pulsed light source is provided with an optical modulator that makes the light intensity distribution of the second pulsed light in a ring shape, and
the optical modulator is a phase mask, a spatial phase modulator, or a spiral phase plate.

4. The applied electron beam device according to claim 1, wherein
the excitation light optical system includes a monitor optical system configured to measure reflected light from the photocathode, and
the monitor optical system includes a ¼ wavelength plate inserted into the optical path of the first pulsed light and the second pulsed light, a reflected light separator inserted into the optical path of the first pulsed light and the second pulsed light and configured to separate reflected light passed through the ¼ wavelength plate from the optical path of the first pulsed light and the second pulsed light, and an image forming optical system configured to form an image of reflected light from the reflected light separator on an imaging device.

5. The applied electron beam device according to claim 4, wherein
the monitor optical system is configured to insert, between the image forming optical system and the reflected light separator, a polarizer that prevents light having the same polarization direction as the reflected light from the reflected light separator from passing through the polarizer.

6. The applied electron beam device according to claim 1, further comprising:
a control device configured to control light intensities of the first pulsed light and the second pulsed light, and a radiation timing of the second pulsed light to the photocathode relative to a radiation timing of the first pulsed light to the photocathode, wherein
the electron optical system includes an aperture configured to limit an opening angle of the electron beam radiated to the sample, and
the light intensity of the second pulsed light and the radiation timing of the second pulsed light to the photocathode relative to the radiation timing of the first pulsed light to the photocathode are optimized based on an image of the sample obtained by irradiating the sample with the electron beam by the electron optical system and a current amount of the electron beam passed through the aperture.

7. An applied electron beam device comprising:
a photocathode including a photoelectric film;
a first pulsed light source configured to emit first pulsed light;
a second pulsed light source configured to emit second pulsed light that is infrared light;
a condensing lens configured to condense the first pulsed light on the photocathode; and
an electron optical system configured to irradiate a sample with an electron beam emitted from the photocathode.

8. The applied electron beam device according to claim 7, wherein
the photoelectric film includes a wide gap semiconductor having a band gap energy of 3 eV or more, and
energy of the second pulsed light is lower than the band gap energy of the wide gap semiconductor, and is equal to or larger than energy of an acceptor level of the wide gap semiconductor.

9. The applied electron beam device according to claim 7, wherein
a wavelength of the second pulsed light is a wavelength at which electrons trapped in a surface state of the photoelectric film are excited to a conduction band or a vacuum level.

10. An applied electron beam device comprising:
a photocathode including a photoelectric film;
a first pulsed light source configured to emit first pulsed light;
a second pulsed light source configured to emit second pulsed light;
a third pulsed light source configured to emit third pulsed light;
an excitation light optical system including a first optical coupler configured to combine an optical path of the second pulsed light and an optical path of the third pulsed light, and a second optical coupler configured to combine pulsed light from the first optical coupler with the first pulsed light;
a condensing lens configured to condense, on the photocathode, the first pulsed light, the second pulsed light, and the third pulsed light that are emitted from the excitation light optical system; and
an electron optical system configured to irradiate a sample with an electron beam emitted from the photocathode, wherein
the photoelectric film includes a wide gap semiconductor having a band gap energy of 3 eV or more, and
a difference between energy of the second pulsed light and energy of the third pulsed light is equal to or larger than energy of an acceptor level of the wide gap semiconductor.

11. The applied electron beam device according to claim 10, wherein
the energy of the second pulsed light and the energy of the third pulsed light are each ½ or less of the band gap energy of the wide gap semiconductor.

12. An applied electron beam device comprising:
a photocathode including a photoelectric film;
a first pulsed light source configured to emit first pulsed light;
a second pulsed light source configured to emit second pulsed light that has a longer wavelength than the first pulsed light and is radially polarized light;
a condensing lens configured to condense the first pulsed light on the photocathode;
a focusing optical system configured to condense the second pulsed light on a condensing position of the first pulsed light on the photocathode;
a control device configured to control a radiation timing of the second pulsed light to the photocathode relative to a radiation timing of the first pulsed light to the photocathode; and
an electron optical system configured to irradiate a sample with an electron beam emitted from the photocathode, wherein
the control device performs control to radiate the first pulsed light in a time zone in which an electric field on a surface of the photoelectric film is positive due to radiation of the second pulsed light.

13. The applied electron beam device according to claim 12, further comprising:
an excitation light optical system configured to emit the first pulsed light and the second pulsed light in a manner of combining an optical path of the first pulsed light and an optical path of the second pulsed light, wherein
the focusing optical system includes a reflective objective lens.

14. The applied electron beam device according to claim 12, wherein
the second pulsed light is incident from a different direction from the first pulsed light, and is condensed at the condensing position of the first pulsed light on the photocathode by a mirror.

15. An electron beam generation method for generating an electron beam from a photocathode including a photoelectric film, the electron beam generation method comprising:
condensing first pulsed light on the photocathode by a condensing lens, and
condensing second pulsed light that has a longer wavelength than the first pulsed light and has a ring-shaped light intensity distribution on a condensing position of the first pulsed light on the photocathode.
